(19) United States
(12) Patent Application Publication
(10) Pub. No.: US 2023/0317438 A1
(43) Pub. Date: Oct. 5, 2023

(54) MAINTENANCE METHOD, METHOD OF MANUFACTURING SEMICONDUCTOR DEVICE, NON-TRANSITORY COMPUTER-READABLE RECORDING MEDIUM AND SUBSTRATE PROCESSING APPARATUS

(71) Applicant: Kokusai Electric Corporation, Tokyo (JP)

(72) Inventors: Teruo YOSHINO, Toyama (JP); Koichiro HARADA, Toyoma (JP); Yukinori ABURATANI, Toyama (JP); Takeshi YASUI, Toyama (JP)

(21) Appl. No.: 18/186,242

(22) Filed: Mar. 20, 2023

(30) Foreign Application Priority Data
Mar. 29, 2022 (JP) 2022-053819

(51) Int. Cl. H01J 37/32; H01L 21/02; C23C 16/34; C23C 16/44

(52) U.S. Cl. CPC H01J 37/3288; H01L 21/02247; H01L 21/0217; H01J 37/32458; C23C 16/345; C23C 16/44; H01J 2237/332; H01J 37/321

(57) ABSTRACT

According to the present disclosure, there is provided a technique capable of repairing a damage due to a surface treatment of a metal material constituting a reaction vessel. According to one aspect of the technique of the present disclosure, there is provided a maintenance method including: (a) performing a substrate processing on a substrate arranged in a reaction vessel at a predetermined temperature by supplying a process gas to the substrate; and (b) performing an oxidation process of repairing a damage due to an alumite treatment on a surface of an aluminum material constituting at least a part of the reaction vessel at a temperature equal to or higher than the predetermined temperature by supplying an oxygen-containing gas into the reaction vessel in a state where there is no substrate in the reaction vessel.

### CROSS REFERENCE TO RELATED APPLICATIONS

This non-provisional U.S. patent application is based on and claims priority under 35 U.S.C. § 119(a)-(d) of Japanese Patent Application No. 2022-053819 filed on Mar. 29, 2022, in the Japanese Patent Office, the entire contents of which are hereby incorporated by reference.

### TECHNICAL FIELD

The present disclosure relates to a maintenance method, a method of manufacturing a semiconductor device, a non-transitory computer-readable recording medium and a substrate processing apparatus.

### BACKGROUND

According to some related arts, as a part of a film-forming process of forming a film on a substrate, a modification process by supplying a plasma-excited process gas to the substrate may be performed.

When the modification process is performed by using the plasma-excited process gas, a surface-treated portion of a metal material constituting a reaction vessel may be damaged.

### SUMMARY

According to the present disclosure, there is provided a technique capable of repairing a damage due to a surface treatment of a metal material constituting a reaction vessel.

According to one aspect of the technique of the present disclosure, there is provided a maintenance method including: (a) performing a substrate processing on a substrate arranged in a reaction vessel at a predetermined temperature by supplying a process gas to the substrate; and (b) performing an oxidation process of repairing a damage due to an alumite treatment on a surface of an aluminum material constituting at least a part of the reaction vessel at a temperature equal to or higher than the predetermined temperature by supplying an oxygen-containing gas into the reaction vessel in a state where there is no substrate in the reaction vessel.

### BRIEF DESCRIPTION OF THE DRAWINGS

FIG. 1 is a diagram schematically illustrating a configuration of a substrate processing apparatus preferably used in one or more embodiments of the present disclosure.

FIG. 2 is a diagram schematically illustrating a principle of generating a plasma in the substrate processing apparatus according to the embodiments of the present disclosure.

FIG. 3 is a block diagram schematically illustrating a configuration of a controller (control structure) and related components of the substrate processing apparatus according to the embodiments of the present disclosure.

FIG. 4 is a flow chart schematically illustrating a substrate processing according to the embodiments of the present disclosure.

FIGS. 5A and 5B are diagrams schematically illustrating a substrate in a modification process (that is, the substrate processing) of modifying a film formed on the substrate by the substrate processing apparatus according to the embodiments of the present disclosure, more specifically, FIG. 5A is a diagram schematically illustrating a cross-section of the substrate with the film formed thereon before performing the modification process, and FIG. 5B is a diagram schematically illustrating the cross-section of the substrate when the film is modified by performing the modification process.

FIG. 6 is a flow chart schematically illustrating an oxidation process according to the embodiments of the present disclosure.

FIGS. 7A through 7C are diagrams schematically illustrating a metal material in the oxidation process according to the embodiments of the present disclosure, more specifically, FIG. 7A is a diagram schematically illustrating a cross-section of the metal material when an alumite layer is provided on an aluminum surface (metal surface) of the metal material, FIG. 7B is a diagram schematically illustrating the cross-section of the metal material when an alumite damage occurs (that is, when the alumite layer is damaged), and FIG. 7C is a diagram schematically illustrating the cross-section of the metal material when the alumite damage is repaired.

### DETAILED DESCRIPTION

### Embodiments of Present Disclosure

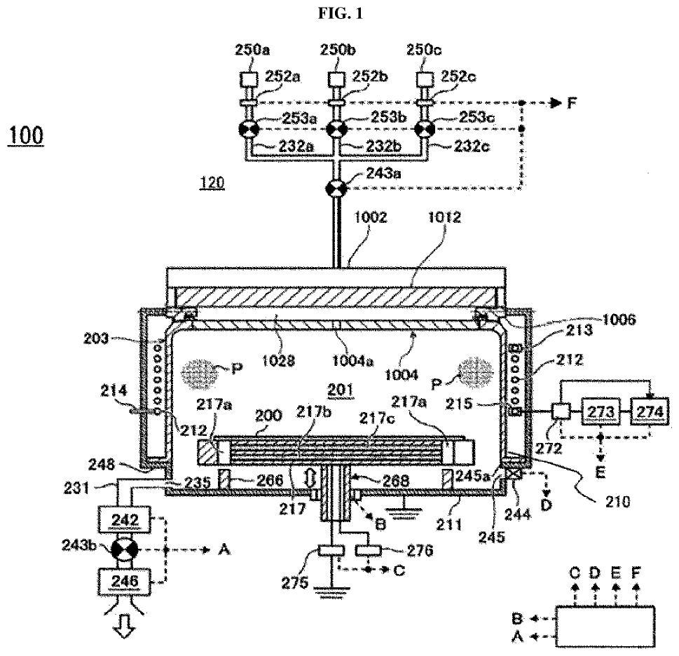

Hereinafter, one or more embodiments (hereinafter, also simply referred to as “embodiments”) according to the technique of the present disclosure will be described with reference to FIGS. 1 through 7C. In the following descriptions of the embodiments, the same or similar reference numerals represent the same or similar components in the drawings, and redundant descriptions related thereto will be omitted. In addition, the drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

Hereinafter, a configuration of a substrate processing apparatus 100 according to the present embodiments will be described below with reference to FIGS. 1 through 3. For example, the substrate processing apparatus 100 according to the present embodiments is configured to mainly perform a modification process on a film formed on a surface of a substrate 200.

The substrate processing apparatus 100 according to the present embodiments includes a process chamber 201, a heating structure, a plate 1004 and a manifold 1006.

The heating structure is configured to be capable of heating an inside of the process chamber 201. For example, the heating structure is constituted by a lamp heater 1002 and a susceptor heater 217b provided in a susceptor 217, which are described later. The lamp heater 1002 may also be simply referred to as a “lamp”. For example, the susceptor heater 217b includes a resistance heater capable of generating a heat by an electric resistance of the susceptor heater 217b itself. The heating structure may be simply referred to as a “heater”.

For example, the plate 1004 refers to a structure constituting a process gas supplier (which is a process gas supply structure or a process gas supply system) described later. For example, the plate 1004 is provided between the lamp heater 1002 and the process chamber 201 in which the substrate 200 is processed. The plate 1004 is configured to be capable of transmitting a radiant heat from the lamp heater 1002 into the process chamber 201. For example, the substrate 200 is a wafer. For example, at least a part of the plate 1004 is made of quartz (transparent quartz) which is a non-metallic transparent material.

The manifold 1006 is arranged so as to face the plate 1004. For example, the manifold 1006 is made of an aluminum material. An oxidation treatment is performed on a surface of the manifold 1006, and more specifically, an alumite layer (or an alumite film or an oxide film) which is an anodized film formed by an alumite treatment (which is an anodic oxidation treatment) is provided on the surface of the manifold 1006. By providing the oxide film on at least a portion of the surface of the manifold 1006 exposed to a process gas described later, it is possible to suppress an occurrence of a metal contamination due to aluminum during a substrate processing described later. Further, the plate 1004 and the manifold 1006 are arranged without contacting each other. Thereby, it is possible to prevent the plate 1004 from being damaged due to a contact between the plate 1004 and the manifold 1006.

### <Process Chamber>

The substrate processing apparatus 100 includes a process furnace in which the substrate 200 is processed by using a plasma. The process furnace is provided with a process vessel (also referred to as a “reaction vessel”) 203 constituting the process chamber 201. The process vessel 203 includes a dome-shaped upper vessel 210 and a bowl-shaped lower vessel 211. By covering the lower vessel 211 with the upper vessel 210, the process chamber 201 is defined. For example, the upper vessel 210 is made of a non-metallic material such as quartz (SiO2), and the lower vessel 211 is made of a metal material such as the aluminum material. Similar to the surface of the manifold 1006, the oxidation treatment is performed on a surface of the lower vessel 211, and more specifically, an alumite layer (or an alumite film or an oxide film) formed by the alumite treatment is provided on the surface of the lower vessel 211. Similar to the manifold 1006, by providing the oxide film on at least a portion of the surface of the lower vessel 211 exposed to the process gas described later, it is possible to suppress the occurrence of the metal contamination due to aluminum during the substrate processing described later.

In addition, a gate valve 244 is provided on a lower side wall of the lower vessel 211. While the gate valve 244 is open, the substrate 200 can be transferred (or loaded) into the process chamber 201 through a loading/unloading port 245 by using a substrate transfer structure (which is a substrate transfer device) (not shown) or can be transferred (or unloaded) out of the process chamber 201 through the loading/unloading port 245 by using the substrate transfer structure. While the gate valve 244 is closed, the gate valve 244 maintains the process chamber 201 airtight.

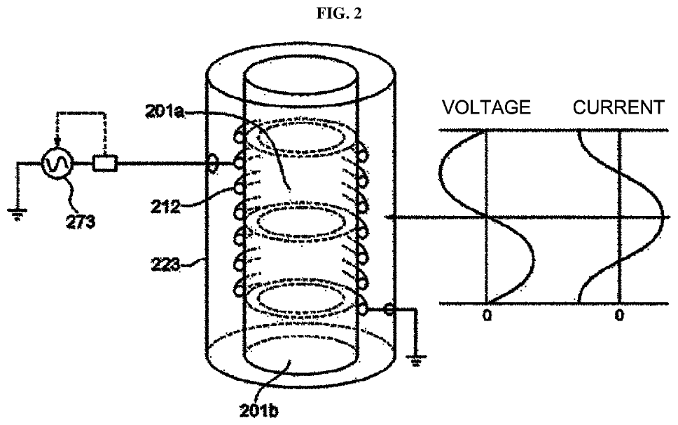

For example, the process chamber 201 includes a plasma generation space 201a (see FIG. 2) and a substrate processing space 201b (see FIG. 2). An electromagnetic field generation electrode 212 is provided around the plasma generation space 201a. For example, the electromagnetic field generation electrode 212 is constituted by a resonance coil. The substrate processing space 201b communicates with the plasma generation space 201a, and the substrate 200 is processed in the substrate processing space 201b. The plasma generation space 201a refers to a space in which the plasma is generated, for example, a space above a lower end of the electromagnetic field generation electrode 212 and below an upper end of the electromagnetic field generation electrode 212 in the process chamber 201. In addition, the substrate processing space 201b refers to a space in which the substrate 200 is processed by the plasma, for example, a space below the lower end of the electromagnetic field generation electrode 212. According to the present embodiments, a diameter of the plasma generation space 201a in a horizontal direction is set to be substantially the same as a diameter of the substrate processing space 201b in the horizontal direction.

### <Susceptor>

The susceptor 217 is provided at a center of a bottom portion of the process chamber 201. The susceptor 217 constitutes a substrate mounting table (which is a substrate support) on which the substrate 200 is placed. For example, the susceptor 217 is made of a non-metallic material such as aluminum nitride (AlN), ceramics and quartz.

The susceptor heater 217b serving as a part of the heating structure is integrally embedded in the susceptor 217. The susceptor heater 217b is configured to heat the substrate 200 such that the surface of the substrate 200 is heated to a temperature within a range from 25° C. to 700° C. when an electric power is supplied to the susceptor heater 217b.

The susceptor 217 is electrically insulated from the lower vessel 211. An impedance adjusting electrode 217c is provided in the susceptor 217. The impedance adjusting electrode 217c is grounded via a variable impedance regulator 275 serving as an impedance adjusting structure. For example, the variable impedance regulator 275 is constituted by components such as a coil (not shown) and a variable capacitor (not shown). The variable impedance regulator 275 is configured to change an impedance of the impedance adjusting electrode 217c by controlling an inductance and resistance of the coil (not shown) and a capacitance value of the variable capacitor (not shown). Thereby, it is possible to control the electric potential (bias voltage) of the substrate 200 via the impedance adjusting electrode 217c and the susceptor 217. However, according to the present embodiments, it is possible to appropriately select whether or not to perform a bias voltage control by using the impedance adjusting electrode 217c.

A susceptor elevator 268 including a driver (which is a driving structure) capable of elevating and lowering the susceptor 217 is provided at the susceptor 217. In addition, a plurality of through-holes 217a are provided at the susceptor 217, and a plurality of substrate lift pins 266 are provided at a bottom surface of the lower vessel 211 at locations corresponding to the plurality of through-holes 217a. For example, at least three of the through-holes 217a and at least three of the substrate lift pins 266 are provided at positions facing one another. When the susceptor 217 is lowered by the susceptor elevator 268, the substrate lift pins 266 pass through the through-holes 217a.

The substrate mounting table (which is the substrate support) according to the present embodiments is constituted mainly by the susceptor 217, the susceptor heater 217b and the impedance adjusting electrode 217c.

### <Lamp Heater>

The lamp heater 1002 serving as a part of the heating structure and capable of radiating an infrared light so as to heat the substrate 200 accommodated in the process chamber 201 is provided at an outer side above the plate 1004 (that is, provided above an upper surface of the plate 1004). The lamp heater 1002 is provided at a location facing the susceptor 217, and is configured to heat the substrate 200 from above the substrate 200. By turning on the lamp heater 1002, it is possible to elevate a temperature of the substrate 200 to a higher temperature (for example, 850° C.) in a shorter time as compared with a case where the susceptor heater 217b alone is used. Further, it is preferable to use the lamp heater 1002 capable of emitting a near infrared light (that is, a light whose peak wavelength preferably is within a range from 800 nm to 1,300 nm, and more preferably, whose peak wavelength is 1,000 nm). For example, a halogen heater may be used as the lamp heater 1002 capable of emitting the near infrared light.

According to the present embodiments, both the susceptor heater 217b and the lamp heater 1002 are provided as the heater (that is, the heating structure). By using the susceptor heater 217b and the lamp heater 1002 together as the heating structure as described above, it is possible to elevate a temperature of the surface of the substrate 200 to a higher temperature, for example, about 850° C.

Further, a lid 1012 is provided between the lamp heater 1002 and the plate 1004. The lid 1012 serves as a transmission window through which the radiant heat from the lamp heater 1002 is transmitted into the process chamber 201. Similar to the plate 1004, for example, the lid 1012 is made of quartz (transparent quartz) which is a non-metallic transparent material. In addition, the lid 1012 is supported by the manifold 1006 from thereunder. That is, a buffer space 1028 is defined by the lid 1012, the plate 1004 and the manifold 1006. A modification gas is supplied into the buffer space 1028 during a modification process described later, and an oxygen-containing gas is supplied during an oxidation process described later.

### <Process Gas Supplier>

The process gas supplier 120 through which the process gas is supplied into the process vessel 203 is configured as follows.

The manifold 1006 is arranged on an edge (periphery) of the plate 1004 so as to face the plate 1004 in a vertical direction, and is provided on the process vessel 203 (that is, the upper vessel 210). The manifold 1006 is cooled by a cooling structure (not shown).

The radiant heat from the lamp heater 1002 reaches an inside of the process chamber 201 through the lid 1012 and the plate 1004.

The plate 1004 is heated by the lamp heater 1002 and the susceptor heater 217b. Further, the plate 1004 may be indirectly heated by, for example, a heat conduction from the process vessel 203 with which the plate 1004 is in contact. In addition, the plate 1004 may be heated by the plasma generated by a plasma generator (which is a plasma generating structure) described later.

A gas ejection port 1004a is provided above the process chamber 201, that is, on an upper portion of the upper vessel 210. The gas ejection port 1004a is configured such that the modification gas serving as the process gas and introduced through a gas introduction port (not shown) can be supplied into the process chamber 201 through the gas ejection port 1004a.

A downstream end of a modification gas supply pipe 232a through which the modification gas is supplied, a downstream end of an oxygen-containing gas supply pipe 232b through which the oxygen-containing gas (such as O2 gas) is supplied and a downstream end of an inert gas supply pipe 232c through which an inert gas is supplied are connected to the gas introduction port so as to be conjoined with one another. A modification gas supply source 250a, a mass flow controller (MFC) 252a serving as a flow rate controller and a valve 253a serving as an opening/closing valve are sequentially provided at the modification gas supply pipe 232a. An oxygen-containing gas supply source 250b, an MFC 252b and a valve 253b are sequentially provided at the oxygen-containing gas supply pipe 232b. An inert gas supply source 250c, an MFC 252c and a valve 253c are sequentially provided at the inert gas supply pipe 232c. A valve 243a is provided on a downstream side of a location where the modification gas supply pipe 232a, the oxygen-containing gas supply pipe 232b and the inert gas supply pipe 232c join. The valve 243a is connected to the gas introduction port which is open to the buffer space 1028. It is possible to supply the process gas (that is, a gaseous mixture of the modification gas, the oxygen-containing gas and the inert gas) into the process chamber 201 via the modification gas supply pipe 232a, the oxygen-containing gas supply pipe 232b and the inert gas supply pipe 232c by opening and closing the valves 253a, 253b, 253c and 243a while adjusting flow rates of the respective gases by the MFCs 252a, 252b and 252c.

The process gas supplier 120 according to the present embodiments is constituted mainly by the modification gas supply pipe 232a, the oxygen-containing gas supply pipe 232b, the inert gas supply pipe 232c, the MFCs 252a, 252b and 252c and the valves 253a, 253b, 253c and 243a. The process gas supplier may also be simply referred to as a “gas supplier” which is a gas supply structure or a gas supply system.

### <Exhauster>

A gas exhaust port 235 through which a gas such as the process gas is exhausted out of the process chamber 201 is provided on a side wall of the lower vessel 211. An upstream end of a gas exhaust pipe 231 is connected to the gas exhaust port 235. An APC (Automatic Pressure Controller) valve 242 serving as a pressure regulator (which is a pressure adjusting structure), a valve 243b serving as an opening/closing valve and a vacuum pump 246 serving as a vacuum exhaust apparatus are provided at the gas exhaust pipe 231.

An exhauster (which is an exhaust structure or an exhaust system) according to the present embodiments is constituted mainly by the gas exhaust port 235, the gas exhaust pipe 231, the APC valve 242 and the valve 243b. The exhauster may further include the vacuum pump 246.

### <Plasma Generator>

The electromagnetic field generation electrode 212 constituted by the resonance coil of a helical shape is provided around an outer periphery of the process chamber 201 so as to surround the process chamber 201, that is, around an outer portion of a side wall of the upper vessel 210. An RF (Radio Frequency) sensor 272, a high frequency power supply 273 and a matcher (which is a matching structure) 274 configured to perform an impedance matching or an output frequency matching for the high frequency power supply 273 are connected to the electromagnetic field generation electrode 212. The electromagnetic field generation electrode 212 extends along an outer peripheral surface of the process vessel 203 while spaced apart from the outer peripheral surface of the process vessel 203, and is configured to generate an electromagnetic field in the process vessel 203 when a high frequency power (RF power) is supplied to the electromagnetic field generation electrode 212. That is, the electromagnetic field generation electrode 212 according to the present embodiments may be constituted by an inductively coupled plasma (ICP) type electrode.

The high frequency power supply 273 is configured to supply the RF power to the electromagnetic field generation electrode 212. The RF sensor 272 is provided at an output side of the high frequency power supply 273. The RF sensor 272 is configured to monitor information of a traveling wave or a reflected wave of the high frequency (RF) power supplied from the high frequency power supply 273. An electric power of the reflected wave monitored by the RF sensor 272 is inputted to the matcher 274, and the matcher 274 is configured to adjust an impedance of the high frequency power supply 273 or a frequency of the RF power output from the high frequency power supply 273 so as to minimize the reflected wave based on the information of the reflected wave inputted from the RF sensor 272.

A winding diameter, a winding pitch and the number of winding turns of the resonance coil serving as the electromagnetic field generation electrode 212 are set such that the resonance coil resonates at a constant wavelength to form a standing wave of a predetermined wavelength. That is, an electrical length of the resonance coil is set to an integral multiple of a wavelength of a predetermined frequency of the high frequency power supplied from the high frequency power supply 273.

For example, a copper pipe, a copper thin plate, an aluminum pipe, an aluminum thin plate and a material obtained by depositing copper or aluminum on a polymer belt may be used as a material constituting the resonance coil serving as the electromagnetic field generation electrode 212. The resonance coil is supported by a plurality of supports (not shown) made of an insulating material, which are provided on an upper end surface of a base plate 248 so as to extend vertically.

Both ends of the resonance coil serving as the electromagnetic field generation electrode 212 are electrically grounded. At least one end of the resonance coil is grounded via a movable tap 213 in order to fine-tune the electrical length of the resonance coil, and the other end of the resonance coil is grounded via a fixed ground 214. Further, a position of the movable tap 213 may be adjusted in order for resonance characteristics of the resonance coil to become approximately the same as those of the high frequency power supply 273. In addition, in order to fine-tune the impedance of the resonance coil, a power feeder (not shown) is constituted by a movable tap 215 between the grounded both ends of the resonance coil.

The plasma generator according to the present embodiments is constituted mainly by the electromagnetic field generation electrode 212, the RF sensor 272 and the matcher 274. In addition, the plasma generator may further include the high frequency power supply 273.

Hereinafter, a principle of generating the plasma in the substrate processing apparatus 100 according to the present embodiments and the properties of the generated plasma will be described with reference to FIG. 2.

A plasma generation circuit constituted by the electromagnetic field generation electrode 212 is configured as an RLC parallel resonance circuit. When the plasma is generated in the plasma generation circuit described above, an actual resonance frequency may fluctuate slightly depending on conditions such as a variation (change) in a capacitive coupling between a voltage portion of the resonance coil and the plasma, a variation in an inductive coupling between the plasma generation space 201a and the plasma and an excitation state of the plasma.

Therefore, according to the present embodiments, in order for the power supply to compensate for a resonance shift in the resonance coil serving as the electromagnetic field generation electrode 212 when the plasma is generated, the RF sensor 272 is configured to detect the electric power of the reflected wave from the resonance coil when the plasma is generated, and the matcher 274 is configured to correct the output of the high frequency power supply 273 based on the detected power of the reflected wave.

Specifically, the matcher 274 is configured to increase or decrease the impedance or the output frequency of the high frequency power supply 273 such that the electric power of the reflected wave is minimized based on the electric power of the reflected wave from the electromagnetic field generation electrode 212 detected by the RF sensor 272 when the plasma is generated.

With such a configuration, as shown in FIG. 2, the high frequency power in accordance with the actual resonance frequency of the resonance coil combined with the plasma is supplied to the electromagnetic field generation electrode 212 according to the present embodiments (or the high frequency power is supplied to match an actual impedance of the resonance coil combined with the plasma). Therefore, the standing wave in which the phase voltage thereof and the opposite phase voltage thereof are always canceled out by each other is generated in the electromagnetic field generation electrode 212. When the electrical length of the resonance coil serving as the electromagnetic field generation electrode 212 and the wavelength of the high frequency power are the same, the highest phase current is generated at an electric midpoint of the electromagnetic field generation electrode 212 (node with zero voltage). Therefore, a donut-shaped induction plasma whose electric potential is extremely low is generated in the vicinity of the electric midpoint of the electromagnetic field generation electrode 212. The donut-shaped induction plasma is hardly capacitively coupled with walls of the process chamber 201 or the susceptor 217.

The electromagnetic field generation electrode 212 is not limited to the ICP type resonance coil as described above. For example, a modified magnetron type (MMT) electrode of a cylindrical shape may be used as the electromagnetic field generation electrode 212.

### <Controller>

A controller 291 serving as a control structure is configured to be capable of controlling the APC valve 242, the valve 243b and the vacuum pump 246 through a signal line “A”, the susceptor elevator 268 through a signal line “B”, a heater power regulator 276 and the variable impedance regulator 275 through a signal line “C”, the gate valve 244 through a signal line “D”, the RF sensor 272, the high frequency power supply 273 and the matcher 274 through a signal line “E”, and the MFCs 252a, 252b and 252c and the valves 253a, 253b, 253c and 243a through a signal line “F”.

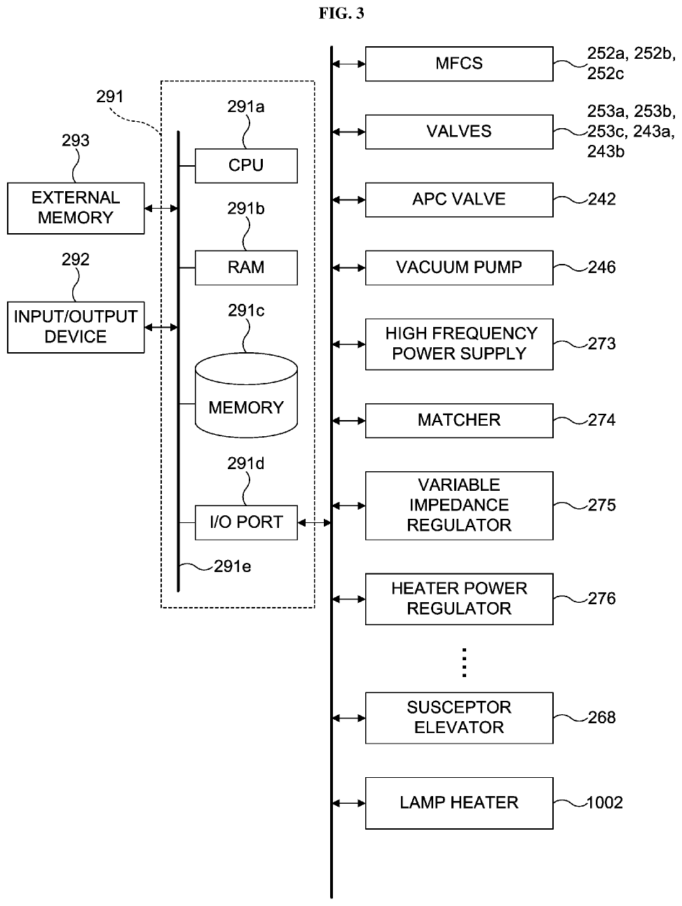

As shown in FIG. 3, the controller 291 serving as the control structure (control apparatus) is constituted by a computer including a CPU (Central Processing Unit) 291a, a RAM (Random Access Memory) 291b, a memory 291c and an I/O port 291d. The RAM 291b, the memory 291c and the I/O port 291d may exchange data with the CPU 291a through an internal bus 291e. For example, an input/output device 292 (which is constituted by components such as a touch panel and a display) may be connected to the controller 291.

The memory 291c may be embodied by a component such as a flash memory and a hard disk drive (HDD). For example, a control program configured to control operations of the substrate processing apparatus 100 and a process recipe in which information such as sequences and conditions of the substrate processing described later is stored may be readably stored in the memory 291c. The process recipe is obtained by combining steps of the substrate processing described later such that the controller 291 can execute the steps to acquire a predetermined result, and functions as a program. Hereinafter, the process recipe and the control program may be collectively or individually referred to as a “program”. Thus, in the present specification, the term “program” may refer to the process recipe alone, may refer to the control program alone, or may refer to both of the process recipe and the control program. Further, the RAM 291b functions as a memory area (work area) where a program or data read by the CPU 291a is temporarily stored.

The I/O port 291d is electrically connected to the components described above such as the MFCs 252a, 252b and 252c, the valves 253a, 253b, 253c, 243a and 243b, the gate valve 244, the APC valve 242, the vacuum pump 246, the RF sensor 272, the high frequency power supply 273, the matcher 274, the susceptor elevator 268, the variable impedance regulator 275, the heater power regulator 276 and the lamp heater 1002.

The CPU 291a is configured to read and execute the control program stored in the memory 291c, and to read the process recipe stored in the memory 291c in accordance with an instruction such as an operation command inputted via the input/output device 292. The CPU 291a is configured to be capable of controlling the operations of the substrate processing apparatus 100 in accordance with the read process recipe. For example, the CPU 291a is configured to be capable of controlling various operations, in accordance with the process recipe, such as: an operation of adjusting an opening degree of the APC valve 242, an opening and closing operation of the valve 243b and a start and stop of the vacuum pump 246 via the I/O port 291d and the signal line “A”; an elevating and lowering operation of the susceptor elevator 268 via the I/O port 291d and the signal line “B”; a power supply amount adjusting operation to the susceptor heater 217b (that is, a temperature adjusting operation) by the heater power regulator 276 and an impedance value adjusting operation by the variable impedance regulator 275 via the I/O port 291d and the signal line “C”; an opening and closing operation of the gate valve 244 via the I/O port 291d and the signal line “D”; controlling operations for the RF sensor 272, the matcher 274 and the high frequency power supply 273 via the I/O port 291d and the signal line “E”; and flow rate adjusting operations for various gases by the MFCs 252a, 252b and 252c and opening and closing operations of the valves 253a, 253b, 253c and 243a via the I/O port 291d and the signal line “F”.

The controller 291 may be embodied by installing the above-described program stored in an external memory 293 into the computer. The memory 291c or the external memory 293 may be embodied by a non-transitory computer readable recording medium. Hereafter, the memory 291c and the external memory 293 may be collectively or individually referred to as a “recording medium”. Thus, in the present specification, the term “recording medium” may refer to the memory 291c alone, may refer to the external memory 293 alone, or may refer to both of the memory 291c and the external memory 293. The program may be provided to the computer without using the external memory 293. For example, the program may be supplied to the computer using a communication structure such as the Internet and a dedicated line.

### (2) Substrate Processing

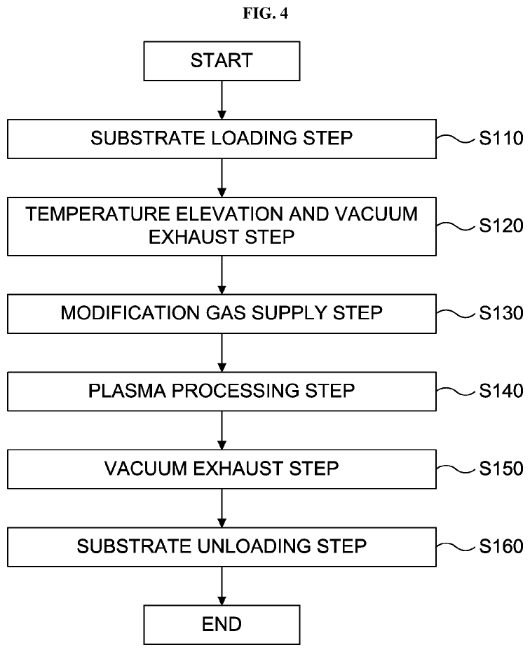

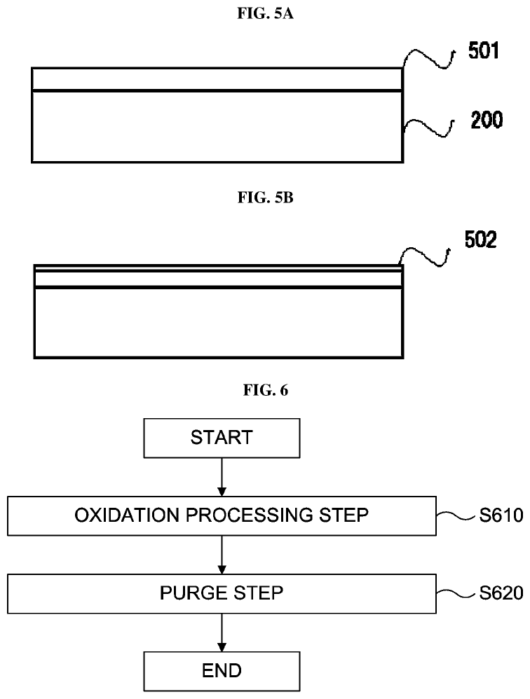

Subsequently, the substrate processing according to the present embodiments of the present disclosure will be described with reference to FIGS. 4, 5A and 5B. FIG. 4 is a flow chart schematically illustrating a process flow of the substrate processing according to the present embodiments. FIGS. 5A and 5B are diagrams schematically illustrating the substrate 200 in the modification process of modifying the film formed on the substrate 200 by using the substrate processing apparatus 100 according to the present embodiments. More specifically, FIG. 5A is a diagram schematically illustrating a cross-section of the substrate 200 with the film formed thereon before performing the modification process, and FIG. 5B is a diagram schematically illustrating the cross-section of the substrate 200 after the film is modified by performing the modification process. For example, the substrate processing, which is a part of the modification process of modifying the film formed on the substrate 200, is performed by the substrate processing apparatus 100 described above. In the following description, operations of components constituting the substrate processing apparatus 100 are controlled by the controller 291.

In addition, a silicon (Si) layer is formed in advance on the surface of the substrate 200 to be processed in the substrate processing according to the present embodiments. In the present embodiments, for example, the modification process serving as a process using the plasma is performed on the silicon layer.

### <Substrate Loading Step S110>

First, the susceptor 217 is lowered to a position of transferring the substrate 200 by the susceptor elevator 268 such that the substrate lift pins 266 pass through the through-holes 217a of the susceptor 217. Subsequently, the gate valve 244 is opened, and the substrate 200 is transferred (loaded) into the process chamber 201 by using the substrate transfer structure (not shown) from a vacuum transfer chamber (not shown) provided adjacent to the process chamber 201. As shown in FIG. 5A, for example, a silicon film 501 is formed on the substrate 200 in advance. The substrate 200 loaded into the process chamber 201 is supported in a horizontal orientation by the substrate lift pins 266 protruding from a surface of the susceptor 217. Thereafter, by elevating the susceptor 217 by the susceptor elevator 268, the substrate 200 is placed on an upper surface of the susceptor 217 and supported by the susceptor 217.

### <Temperature Elevation and Vacuum Exhaust Step S120>

Subsequently, the temperature of the substrate 200 loaded into the process chamber 201 is elevated. For example, the susceptor heater 217b is heated to 700° C. in advance. Further, by turning on the lamp heater 1002, for example, the substrate 200 placed on the susceptor 217 is heated to a predetermined temperature within a range from 700° C. to 850° C., preferably from 750° C. to 850° C. In the step S120, for example, the substrate 200 is heated such that the temperature of the substrate 200 reaches and is maintained at 750° C. The substrate 200 is heated by the infrared light radiated from the susceptor heater 217b and the lamp heater 1002. A process temperature of the substrate 200 is preferably as high as possible for a purpose of further improving an effect of modifying the film. Thus, the process temperature of the substrate 200 is set to the predetermined temperature of 700° C. or higher. When the process temperature of the substrate 200 is lower than 700° C., the effect of modifying the film may not be sufficiently obtained. Further, when the process temperature of the substrate 200 is higher than 850° C., unintended phenomena may occur in the film. Thus, by setting the process temperature of the substrate 200 to the predetermined temperature within the range from 700° C. to 850° C., it is possible to sufficiently obtain the effect described above, and it is also possible to avoid an occurrence of the unintended phenomena. Further, while the substrate 200 is being heated, the vacuum pump 246 vacuum-exhausts an inner atmosphere of the process chamber 201 through the gas exhaust pipe 231 such that an inner pressure of the process chamber 201 reaches and is maintained at a predetermined pressure. The vacuum pump 246 vacuum-exhausts the inner atmosphere of the process chamber 201 at least until a substrate unloading step S160 described later is completed. In the present specification, a notation of a numerical range such as “from 700° C. to 850° C.” means that a lower limit and an upper limit are included in the numerical range. Therefore, for example, a numerical range “from 700° C. to 850° C.” means a range equal to or higher than 700° C. and equal to or less than 850° C. The same also applies to other numerical ranges described herein.

Further, for convenience of explanation, the present embodiments will be described by way of an example in which the processing temperature (which is the temperature of the substrate 200) and an inner temperature of the process vessel 203 are assumed to be substantially the same. However, the process temperature may be different from the inner temperature of the process vessel 203. In a case where the process temperature is different from the inner temperature of the process vessel 203, for example, a temperature of a predetermined portion in the process vessel 203 in the present step may be regarded as a predetermined temperature of the inner temperature of the process vessel 203 in the modification process, and the temperature of the predetermined portion in the process vessel 203 in an oxidation processing step S610 described later may be regarded as a predetermined temperature of the inner temperature of the process vessel 203 in the oxidation process.

### <Modification Gas Supply Step S130>

Subsequently, a supply of the modification gas is started. Specifically, the valve 253a is opened, and the supply of the modification gas into the process chamber 201 is started while a flow rate of the modification gas is adjusted by the MFC 252a. Simultaneously with the supply of the modification gas, the valve 253c may be opened, and the inert gas may be supplied into the process chamber 201 while a flow rate of the inert gas is adjusted by the MFC 252c.

For example, a nitrogen (N)-containing gas such as nitrogen (N2) gas and ammonia (NH3) gas, a hydrogen (H)-containing gas such as hydrogen (H2) gas, a rare gas such as helium (He) gas, argon (Ar) gas, neon (Ne) gas and xenon (Xe) gas or a mixed gas in which two or more of the gases described above are appropriately mixed may be used as the modification gas. It is preferable that the modification gas is substantially free of oxygen. For example, the N2 gas or the rare gas described above may be used as the inert gas. For example, one or more gases exemplified as the rare gas may be used as the inert gas. The same also applies to the steps described below.

Further, the inner atmosphere of the process chamber 201 is appropriately exhausted by adjusting the opening degree of the APC valve 242 such that the inner pressure of the process chamber 201 reaches and is maintained at a predetermined pressure. The modification gas is continuously supplied into the process chamber 201 while the inner atmosphere of the process chamber 201 is appropriately exhausted until a plasma processing step S140 described later is completed.

### <Plasma Processing Step S140>

When the inner pressure of the process chamber 201 is stabilized, a supply (application) of the high frequency power to the electromagnetic field generation electrode 212 from the high frequency power supply 273 is started. Thereby, a high frequency electric field is formed in the plasma generation space 201a to which the modification gas is supplied, and the donut-shaped induction plasma whose density of the plasma is the highest is excited by the high frequency electric field at a height corresponding to the electric midpoint of the electromagnetic field generation electrode 212 in the plasma generation space 201a. The process gas containing the modification gas in a plasma state is plasma-excited and dissociates. As a result, a reactive species such as radicals (active species) and ions of a predetermined element can be generated.

For example, process conditions of the present step are as follows:
A supply flow rate of the modification gas to be plasma-excited: from 1,000 sccm to 10,000 sccm;
The RF power: from 1 W to 1,500 W, preferably from 1 W to 1,000 W;
A supply time (time duration) of supplying the inert gas: from 10 seconds to 1,200 seconds;
The process temperature: from 700° C. to 850° C., preferably from 750° C. to 850° C.; and
A process pressure: from 0.5 Pa to 100 Pa, preferably from 0.5 Pa to 10 Pa.

The radicals generated by the induction plasma and non-accelerated ions are uniformly supplied onto the substrate 200 placed on the susceptor 217 in the substrate processing space 201b. Then, the radicals and the ions uniformly supplied onto the substrate 200 uniformly react with the silicon film 501 formed on the surface of the substrate 200. Thereby, at least a surface of the silicon film 501 is modified into a modification layer 502. Specifically, at a high temperature of about 700° C. to 850° C., by reacting the reactive species supplied as described above with the film (that is, the silicon film 501), impurities contained in the film can be removed, and defects in a molecular structure of the film can be complemented by the reactive species. (that is, the film is modified). In other words, by performing the plasma processing step S140 according to the present embodiments, it is possible to remove the impurities contained in the film, and it is also possible to repair a surface layer of the film. As a result, it is possible to improve properties of the film (for example, properties as an insulating film). For example, when the modification gas is the nitrogen-containing gas, by reacting the reactive species containing nitrogen with silicon, at least a part of the surface of the silicon film 501 is modified into a silicon nitride film serving as the modification layer 502.

After a predetermined process time has elapsed, the supply of the high frequency power from the high frequency power supply 273 is stopped to stop a plasma discharge in the process chamber 201. In addition, the valve 253a is closed to stop the supply of the modification gas into the process chamber 201. Simultaneously, the valve 253c may be closed to stop a supply of the inert gas into the process chamber 201. Thereby, the plasma processing step S140 is completed.

### <Vacuum Exhaust Step S150>

After the supply of the modification gas is stopped, the inner atmosphere of the process chamber 201 is vacuum-exhausted through the gas exhaust pipe 231. As a result, a residual gas in the process chamber 201 such as the modification gas is exhausted out of the process chamber 201. Thereafter, the opening degree of the APC valve 242 is adjusted such that the inner pressure of the process chamber 201 is adjusted to the same pressure as that of the vacuum transfer chamber (not shown) provided adjacent to the process chamber 201.

### <Substrate Unloading Step S160>

Thereafter, after the inner pressure of the process chamber 201 is adjusted to a predetermined pressure, the susceptor 217 is lowered to the position of transferring the substrate 200 until the substrate 200 is supported by the substrate lift pins 266. Then, the gate valve 244 is opened, and the substrate 200 is transferred (or unloaded) out of the process chamber 201 by using the substrate transfer structure (not shown). Thereby, the substrate processing according to the present embodiments is completed.

### (3) Maintenance Process (Oxidation Process for Aluminum Material)>

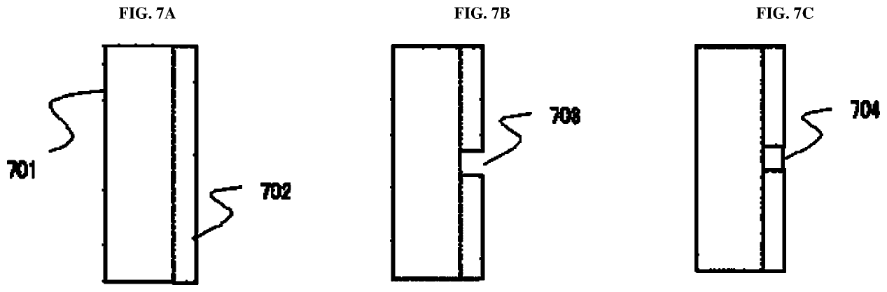

As described above, the manifold 1006 and the lower vessel 211 may be made of the aluminum material which is the metal material. When an aluminum surface of the aluminum material is directly exposed in the process vessel 203, an element such as aluminum contained in the aluminum material may be released into the process vessel 203 by performing the modification process. Further, in a processing of the substrate 200 such as a film-forming process, the element such as aluminum released as described above may enter (or be taken into) the substrate 200. That is, a metal contamination may occur. In order to prevent such a contamination, as shown in FIG. 7A, an alumite layer 702 formed by the alumite treatment (which is a surface treatment) is provided on an aluminum surface 701 of each aluminum material. FIGS. 7A through 7C are diagrams schematically illustrating a side surface (which faces the process chamber 201) of the manifold 1006. However, by performing a plasma modification process (that is, the modification process described above) by the modification gas substantially free of oxygen under, for example, a high temperature of 700° C. or higher, as shown in FIG. 7B, an alumite damage (for example, a peeling, a fissure and a crack) 703 may occur at the alumite layer 702, and thereby, the metal contamination may occur due to aluminum exposed by an occurrence of the alumite damage 703. The alumite damage 703 is generated by a drastic increase in a thermal expansion difference between the aluminum surface 701 and the alumite layer 702 due to a rapid temperature elevation by the lamp heater 1002. Therefore, when the alumite damage 703 occurs, the oxidation process is performed so as to repair the alumite damage 703 of the aluminum material constituting the process vessel 203 such as the manifold 1006 and the lower vessel 211.

FIG. 6 is a flow chart schematically illustrating a process flow of the oxidation process described above.

As described above, the process flow according to the present embodiments shown in FIG. 4 includes (a) performing the modification process on the substrate at a predetermined temperature by supplying the modification gas to the substrate 200 arranged in the reaction vessel. Further, the process flow according to the present embodiments shown in FIG. 6 includes (b) performing the oxidation process at a temperature equal to or higher than the predetermined temperature of (a) by supplying the oxidation-containing gas into the reaction vessel in a state where there is no substrate in the reaction vessel, and thereby repairing a damage due to the alumite treatment (that is, the alumite damage) on the aluminum surface of the aluminum material constituting at least a part of the reaction vessel.

### <Oxidation Processing Step S610>

After the substrate unloading step S160 in FIG. 4, that is, after the substrate 200 (which is modified) is unloaded, the oxygen-containing gas is supplied into the process vessel in a state where there is no substrate in the process vessel. Specifically, after a shutter such as the gate valve 244 is closed, the valve 253b is opened, and a supply of the oxygen-containing gas into the process chamber 201 is started while a flow rate of the oxygen-containing gas is adjusted by the MFC 252b. Simultaneously with the supply of the oxygen-containing gas, the valve 253c may be opened, and the inert gas may be supplied into the process chamber 201 while the flow rate of the inert gas is adjusted by the MFC 252c.

In the present step, by turning on the lamp heater 1002 and the susceptor heater 217b, an inside of the process vessel is heated to a temperature equal to or higher than that in the modification process. For example, when the temperature in the modification process is 750° C., the temperature in the oxidation processing step S610 is set to 750° C. to 850° C. In the oxidation processing step S610, an oxidation annealing is performed by using the oxygen-containing gas in a non-plasma state (which is not plasma-excited), that is, the oxygen-containing gas that is thermally excited.

For example, process conditions of the present step are as follows:
A supply flow rate of the oxygen-containing gas: from 0.1 slm to 10 slm;
A supply flow rate of the inert gas: from 0 slm to 10 slm;
A supply time (time duration) of supplying each gas: from 15 minutes to 60 minutes;
The process temperature (that is, the inner temperature of the process chamber 201): from 700° C. to 850° C., preferably from 750° C. to 850° C.; and
The process pressure (that is, the inner pressure of the process chamber 201): from 1 Pa to 2,000 Pa, preferably from 1 Pa to 1,000 Pa.

Under such process conditions described above, as shown in FIG. 7C, it is possible to form an oxide film 704 on a location where the alumite damage 703 occurs by performing the oxidation process by supplying the oxygen-containing gas to a location of the aluminum material where the alumite damage 703 occurs. In particular, since the radiant heat from the lamp heater 1002 promotes a thermal oxidation, it is possible to form the oxide film 704.

By performing the oxidation process, it is possible to form the oxide film 704 (whose thickness is within a range from 1 μm to 10 μm, preferably from 5 μm to 10 μm) on the location of the aluminum material where the alumite damage 703 occurs. When the thickness of the oxide film 704 is less than 1 μm, a restoration (repair) of the alumite damage 703 may not be performed sufficiently, and the contamination (metal contamination) due to aluminum is likely to occur. By setting the thickness of the oxide film 704 to 1 μm or more, it is possible to suppress the occurrence of the contamination due to aluminum. Further, by setting the thickness of the oxide film 704 to 5 μm or more, it is possible to more reliably suppress the occurrence of the contamination due to aluminum. On the other hand, when the thickness of the oxide film 704 is greater than 10 μm, a film peeling is likely to occur due to a thermal expansion when a high temperature process is performed. By setting the thickness of the oxide film 704 to 10 μm or less, it is possible to suppress an occurrence of the film peeling due to the thermal expansion when the high temperature process is performed. As described above, when the thickness of the oxide film 704 is within the range from 1 μm to 10 μm, preferably from 5 μm to 10 μm, it is possible to sufficiently prevent the contamination due to aluminum.

According to the present embodiments, by performing the oxidation process (that is, the oxidation processing step S610) at the temperature equal to or higher than that in the modification process, it is possible to repair the alumite damage 703. For example, by oxidizing the location (where the alumite damage 703 occurs) at the temperature higher than a modification temperature (that is, the temperature in the modification process), it is possible to reduce the thermal expansion of a repaired portion when a subsequent modification process is performed, and it is also possible to reduce a possibility that the repaired portion will be damaged again. Therefore, it is possible to reduce the possibility that the repaired portion is damaged again when the subsequent modification process is performed.

According to the present embodiments, the lamp heater 1002 is used for heating the process vessel to a higher temperature. For example, the lamp heater 1002 heats the process vessel by radiation. From a point of view of using the lamp heater 1002, when the pressure in the oxidation process is lower than that in the modification process, it is possible to further promote the oxidation process by heating the process vessel by the radiation.

Further, according to the present embodiments, by using a thermal oxidation process without using the plasma (that is, a non-plasma thermal oxidation process), it is possible to prevent the damage due to the plasma without generating an intense oxidation due to the plasma, and it is also possible to effectively repair the location where the alumite damage occurs.

For example, a gas such as oxygen (O2) gas, ozone (O3) gas, water vapor (H2O) gas, hydrogen peroxide (H2O2) gas, nitrous oxide (N2O) gas, nitrogen monoxide (NO) gas, nitrogen dioxide (NO2) gas, carbon monoxide (CO) gas and carbon dioxide (CO2) gas may be used as the oxygen-containing gas. Further, one or more of the gases described above may be used as the oxygen-containing gas.

### <Purge Step S620>

After the oxidation processing step S610 is completed, the valve 243b is closed to stop the supply of the oxygen-containing gas into the process chamber 201. Thereafter, the inert gas serving as the purge gas is supplied into the process chamber 201 from the inert gas source 250c. When supplying the inert gas, by applying the plasma power to the electromagnetic field generation electrode 212 to plasma-excite the inert gas, an inert gas plasma purge operation using an activated inert gas may be performed.

Thereby, the inside of process chamber 201 is purged with the inert gas such that a residual gas such as the oxygen-containing gas and the reaction by-products remaining in the process chamber 201 are removed from the process chamber 201 (purge step). In this manner, the inner atmosphere of the process chamber 201 is purged with the inert gas before the modification process is restarted. By performing the present step, it is possible to remove oxygen in the reaction vessel. Thereafter, the inner atmosphere of the process chamber 201 is replaced with the inert gas (substitution by the inert gas), and the inner pressure of the process chamber 201 is returned to the normal pressure (returning to the atmospheric pressure).

By performing the steps of the oxidation process described above, it is possible to repair the alumite damage on the aluminum material. Further, according to the present embodiments, it is possible to repair the damage even when the aluminum material with the damage is attached to the substrate processing apparatus 100. Therefore, it is possible to eliminate a troublesome step such as a step of removing the aluminum material where the alumite damage occurs from the substrate processing apparatus 100 before performing the alumite treatment.

As described above, the oxidation process is performed while the shutter is closed. That is, the oxidation process is performed without loading (or accommodating) the substrate 200 (for example, a product wafer or a dummy wafer, which is processed by the modification process) into the process vessel. As a result, the film formed on the surface of the substrate 200 (the product wafer or the dummy wafer) after the modification process is not subjected to the oxidation process described above. Thereby, the film formed on the surface of the substrate 200 (the product wafer or the dummy wafer) remains intact without being oxidized.

For example, it is possible to recognize the alumite damage on the aluminum material by performing a regular maintenance. Further, when the alumite damage occurs, the temperature of the substrate during the modification process may decrease due to the aluminum material with the alumite damage. Therefore, by monitoring the temperature of the substrate during the modification process, in a case where the temperature of the substrate is equal to or lower than a predetermined temperature (or in a case where an output of the heating structure (that is, the susceptor heater 217b and/or the lamp heater 1002) (which is feed-back controlled so as to maintain the temperature of the substrate constant) is equal to or greater than a predetermined value), it is determined that the alumite damage occurs, and the substrate processing apparatus 100 may be configured to be capable of outputting an alarm via the input/output device 292.

The susceptor 217 may be lowered by the susceptor elevator 268 when the oxidation process is being performed. In such a case, it is possible to sufficiently expose a side surface of the lower vessel 211 and the like to a radiant light emitted from the lamp heater 1002 and/or the susceptor heater 217b, and it is also possible to sufficiently oxidize the lower vessel 211 by further promoting the heating of the lower vessel 211. Alternatively, the susceptor 217 may be elevated by the susceptor elevator 268 when the oxidation process is being performed. In such a case, it is possible to perform the oxidation process while reproducing conditions of the modification process. Still alternatively, the susceptor 217 may be lowered and elevated in the single oxidation process.

It is preferable that recipes used in various processes described above are prepared individually in accordance with process contents and stored in the memory 291c via an electric communication line or the external memory 293. When starting various processes, it is preferable that the CPU 291a selects an appropriate recipe among the recipes stored in the memory 291c in accordance with the process contents. Thus, various films of different composition ratios, qualities and thicknesses can be formed in a reproducible manner by using a single substrate processing apparatus. In addition, since a burden on an operating personnel of the substrate processing apparatus can be reduced, various processes can be performed quickly while avoiding a malfunction of the substrate processing apparatus.

The recipe described above is not limited to creating a new recipe. For example, the recipe may be prepared by changing an existing recipe stored in the substrate processing apparatus in advance. When changing the existing recipe to a new recipe, the new recipe may be installed in the substrate processing apparatus via the electric communication line or the recording medium in which the new recipe is stored. Further, the existing recipe already stored in the substrate processing apparatus may be directly changed to a new recipe by operating the input/output device 292 of the existing substrate processing apparatus.

### Other Embodiments of Present Disclosure

While the technique of the present disclosure is described in detail by way of the embodiments described above, the technique of the present disclosure is not limited thereto. The technique of the present disclosure may be modified in various ways without departing from the scope thereof.

For example, the embodiments described above are described by way of an example in which a single wafer type substrate processing apparatus capable of processing one or several substrates at a time is used to form the film. However, the technique of the present disclosure is not limited thereto. For example, the technique of the present disclosure may be preferably applied when a batch type substrate processing apparatus capable of simultaneously processing a plurality of substrates is used to form the film. For example, the embodiments described above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

The process sequences and the process conditions of each process using the substrate processing apparatuses described above may be substantially the same as those of the embodiments described above. Even in such a case, the same effects according to the embodiments described above may also be obtained similarly.

Further, the embodiments described above and modified examples described above may be appropriately combined. The process sequences and the process conditions of each combination thereof may be substantially the same as those of the embodiments described above.

According to some embodiments of the present disclosure, it is possible to repair the damage due to the surface treatment of the metal material constituting the reaction vessel.

What is claimed is:

1. A maintenance method comprising:
(a) performing a substrate processing on a substrate arranged in a reaction vessel at a predetermined temperature by supplying a process gas to the substrate; and
(b) performing an oxidation process of repairing a damage due to an alumite treatment on a surface of an aluminum material constituting at least a part of the reaction vessel at a temperature equal to or higher than the predetermined temperature by supplying an oxygen-containing gas into the reaction vessel in a state where there is no substrate in the reaction vessel.

2. The maintenance method of claim 1, wherein the substrate processing is performed by using a plasma of a nitrogen-containing gas, and the oxidation process is performed by using the oxygen-containing gas in a non-plasma state.

3. The maintenance method of claim 1, wherein the predetermined temperature is within a range from about 700° C. to about 850° C.

4. The maintenance method of claim 1, wherein an alumite layer is formed on the surface of the aluminum material, and the predetermined temperature is a temperature at which a thermal expansion difference occurs between the aluminum material and the alumite layer.

5. The maintenance method of claim 4, wherein the damage due to the alumite treatment comprises an exposure of the aluminum material.

6. The maintenance method of claim 1, wherein the reaction vessel is provided with an upper vessel, a quartz window provided above the upper vessel and a lamp arranged on an upper portion of the quartz window, and
wherein the aluminum material is arranged on a side surface of the quartz window.

7. The maintenance method of claim 1, wherein the reaction vessel is provided with a lower vessel, and
wherein an inner surface of the lower vessel is constituted by the aluminum material processed by the alumite treatment.

8. The maintenance method of claim 1, wherein the oxidation process is performed in a state where a position of a susceptor in the reaction vessel is lowered from a processing position of the susceptor at which the substrate processing is performed.

9. The maintenance method of claim 1, wherein the oxidation process is performed in a state where a position of a susceptor in the reaction vessel is same as a processing position of the susceptor at which the substrate processing is performed.

10. The maintenance method of claim 1, wherein a pressure at which the oxidation process is performed is lower than a pressure at which the substrate processing is performed.

11. The maintenance method of claim 1, further comprising:
(c) detecting the damage due to the alumite treatment and outputting an alarm based on a temperature of the substrate or an output of a lamp heater when the substrate processing is performed.

12. The maintenance method of claim 1, wherein, in (b), an oxidation film is formed on a location where the damage due to the alumite treatment occurs, and
wherein a thickness of the oxidation film is 1 μm or more and 10 μm or less.

13. The maintenance method of claim 1, wherein, in (b), an oxidation film is formed on a location where the damage due to the alumite treatment occurs, and
wherein a thickness of the oxidation film is 5 μm or more and 10 μm or less.

14. The maintenance method of claim 1, further comprising:
(d) generating a plasma of an inert gas in the reaction vessel after (b).

15. The maintenance method of claim 1, wherein the substrate processing comprises a modification process of modifying a film formed on the substrate.

16. The maintenance method of claim 1, further comprising:
(e) loading the substrate into the reaction vessel, wherein at least the part of the reaction vessel is constituted by the aluminum material on which the alumite treatment is performed and a surface of the aluminum material on which the alumite treatment is performed is exposed in the reaction vessel;
(f) elevating an inner temperature of the reaction vessel to the predetermined temperature; and
(g) unloading the substrate processed in (a) out of the reaction vessel,
wherein (e) and (f) are performed before (a) and (g) is performed after (a).

17. A maintenance method comprising:
after a substrate is processed in a reaction vessel at a predetermined temperature, performing an oxidation process of repairing a damage due to an alumite treatment on a surface of an aluminum material constituting at least a part of the reaction vessel at a temperature equal to or higher than the predetermined temperature by supplying an oxygen-containing gas into the reaction vessel in a state where there is no substrate in the reaction vessel.

18. A method of manufacturing a semiconductor device, comprising the maintenance method of claim 1.

19. A non-transitory computer-readable recording medium storing a program that causes a substrate processing apparatus, by a computer, to perform a process comprising the maintenance method of claim 1.

20. A substrate processing apparatus comprising:
a reaction vessel;
a process gas supplier through which a process gas is supplied to the reaction vessel;
an oxygen-containing gas supplier through which an oxygen-containing gas is supplied to the reaction vessel;
an exciter capable of plasma-exciting the process gas; and
a controller configured to be capable of controlling the process gas supplier, the oxygen-containing gas supplier and the exciter so as to perform:
(a) performing a substrate processing on a substrate arranged in the reaction vessel at a predetermined temperature by supplying the process gas to the substrate; and
(b) performing an oxidation process of repairing a damage due to an alumite treatment on a surface of an aluminum material constituting at least a part of the reaction vessel at a temperature equal to or higher than the predetermined temperature by supplying the oxygen-containing gas into the reaction vessel in a state where there is no substrate in the reaction vessel.
